(19) United States
(12) Patent Application Publication
(10) Pub. No.: US 2006/0110876 A1
(43) Pub. Date: May 25, 2006

(54) MOS transistor with reduced kink effect and method for the manufacture thereof

(75) Inventors: Volker Dudek, Brackenheim (DE); Stefan Schwantes, Heilbronn (DE)

Correspondence Address: BIRCH STEWART KOLASCH & BIRCH, PO BOX 747, FALLS CHURCH, VA, 22040-0747, US

(73) Assignee: ATMEL GERMANY GMBH, Heilbronn (DE)

(21) Appl. No.: 11/285,113

(22) Filed: Nov. 23, 2005

(30) Foreign Application Priority Data
Nov. 25, 2004 (DE) 10 2004 058 468.0

(51) Int. Cl. H01L 21/8238; H01L 29/76

(52) U.S. Cl. 438/219; 257/510; 438/221; 257/374

(57) ABSTRACT

A lateral MOS transistor is provided with a channel region, which has a channel width delimited by dielectric-filled trenches and which is covered with a gate dielectric, whose layer thickness varies over the channel width. An outer layer thickness, which the gate dielectric has over junctions of the channel region to the dielectric-filled trenches, is greater than an inner layer thickness, which the dielectric has over a central part of the channel region. Furthermore, a method for manufacturing the MOS transistor is provided.

This nonprovisional application claims priority under 35 U.S.C. § 119(a) on Patent Application No. 10 2004 058 468.0, which was filed in Germany on Nov. 25, 2004, and which is herein incorporated by reference.

### BACKGROUND OF THE INVENTION

1. Field of the Invention

The present invention relates to a MOS transistor with a channel region, which has a channel width delimited by dielectric-filled trenches and which is covered with a gate dielectric, whose layer thickness varies over the channel width.

The invention relates further to a method for manufacturing a MOS transistor with a channel region, which has a channel width delimited by dielectric-filled trenches and which, in an intermediate step of the method, is covered with a gate dielectric, whose layer thickness varies over the channel width.

2. Description of the Background Art

In conventional MOS transistors, a reduced thickness of the gate layer arises at the edges of an active region. This will be explained in greater detail below. Conventional enhancement-type MOS transistors have a MOS diode comprising a layer sequence of a highly conductive gate electrode (e.g., metal), a dielectric gate layer (e.g., oxide), and semiconductor layer (semiconductor) of a first conductivity type. The MOS diode is adjacent to semiconductor layers of a second conductivity type, so that it is delimited by two pn junctions. A highly doped source region is created on one side of the MOS diode and a highly doped drain region in the semiconductor material of the second conductivity type on the other side. With application of voltage between the source region and drain region, one of the two pn junctions, which delimit the MOS diode, blocks, so that the voltage applied between the drain region and source region cannot push any current through the MOS diode. Only when an inversion layer is created at the semiconductor/dielectric interface of the MOS diode by a sufficiently high gate electrode potential does the previously blocking pn junction disappear in the cross section of the inversion layer, also designated as a channel, and the voltage between the drain region and source region pushes a current through the MOS diode.

The MOS diode has a surface area, which is defined by the product of the channel length and channel width of the channel region. In this context, the channel length is understood to be the distance between the indicated pn junctions, and the channel width, the extension of the channel region parallel to the pn junctions. Individual MOS transistors in an integrated circuit are insulated from one another by field oxide. The field oxide can be produced by local oxidation (LOCOS=local oxidation of silicon) or in the form of dielectric-filled trench structures. Such trench structures are produced as is known by an STI process (STI=shallow trench isolation). In comparison with the LOCOS technique, the STI technique makes possible a higher packing density of components and is therefore preferred at a high integration density.

The potential difference between the source region and gate electrode, in which the inversion clearly appears (strong inversion), is designated as a threshold voltage, as is well-known. In the subthreshold voltage range, an ideal characteristic of the drain current plotted versus the gate voltage proceeds exponentially, therefore linearly in a logarithmic plot of the drain current. MOS transistors, which are used in highly sensitive analog circuits, are to exhibit this linearity as precisely as possible. A deviation from the exponential dependence becomes apparent as a sharp bend in the logarithmically plotted characteristic, which in the English technical literature is also called a “hump” or “kink.” This “kink” effect can be so pronounced that the MOS transistors affected thereby cannot be used in highly sensitive analog circuits. The kink effect usually occurs only in relation to STI oxides, but not in a relation to LOCOS isolations.

### SUMMARY OF THE INVENTION

On this background, the object of the invention is to provide a MOS transistor, which can be integrated with high packing densities and which exhibits no interfering kink effect. Furthermore, another object of the invention is to provide a method for manufacturing the transistor.

This object is achieved with a transistor of the aforementioned type in that a first layer thickness, which the gate dielectric has over junctions of the channel region to the dielectric-filled trenches, is greater than a second layer thickness, which the dielectric has over a central part of the channel region.

Furthermore, this object is achieved by a method of the aforementioned type in that the step of covering the channel region with the gate dielectric has a step for creating a dielectric layer over the channel region, a step for the lithographic differentiation of a central part of the channel region from the peripheral parts of the channel region at junctions to the dielectric trenches, and a step for creating different layer thicknesses of the gate dielectric on the lithographically different parts of the channel region, in which a first layer thickness, arising over the peripheral parts, is greater than a second gate dielectric layer thickness, arising over the central part, of the gate dielectric.

In addition, the invention is based on the insight that the interfering kink effect is caused by an undesirable decline in the thickness of gate dielectrics at the boundary between the oxide fillings of shallow trenches and active regions of MOS diodes of the MOS transistors. The decline in thickness occurs because, before the creation of the dielectric gate layer, dopants are repeatedly implanted in the active regions of more recent MOS transistors. Before such implantations, the wafer surface is usually covered by scattering oxides, which must be removed after each implantation by cleaning steps acting selectively on oxide. In such cleaning steps acting selectively on oxide, more material is successively removed from the trench structures filled for the most part with oxide as the dielectric than from the active region. As a result, rounded steps or edges form at the junctions of the trench structures to the active regions; during the subsequent covering of the wafer surface with a gate dielectric, these are covered more thinly with material than horizontal regions.

The thinner gate layer in the edge region in later operation weakens the punching through of the field of the gate electrode into the underlying semiconductor material correspondingly less greatly than the thicker gate layer in the horizontal, central regions of the active material. Below the thin gate layer regions, therefore, greater electrical fields predominate in the active semiconductor material of the MOS diode, which allows the inversion under the thin gate layer regions to begin earlier than in central regions of the active material. The entire component therefore behaves as a parallel connection of several MOS transistors with different threshold voltages and thereby different characteristics. The resulting overlapping of the characteristics leads to the aforementioned interfering sharp bend (kink) in the characteristic of the entire component.

Because the invention, both in its device aspects and in its methods aspects, provides increased gate dielectric layer thicknesses at the junctions, the more easily occurring inversion in the marginal regions of the active material of the MOS does not occur. As a result, the interfering kink effect is totally eliminated by the removal of its cause.

In regard to embodiments of the method, it is preferred that the step for creating a dielectric layer over the channel region has a step of a nonselective creation of a first thickness of the dielectric layer.

The nonselective creation of the dielectric layer first has a leveling effect on the unevenness of the structure, as occurs, for example, for the named reasons at the junctions of the active regions to dielectric-filled trench structures.

It is also preferred that the step of the nonselective creation of the first thickness has a step of the epitaxial growing of an ONO layer.

An ONO layer is understood to be a layer sequence of a first partial oxide layer, a nitride layer, and a second partial oxide layer. This layer sequence creates a so-called ONO (oxide-nitride-oxide) multilayer dielectric, which is characterized by an especially high breakdown field strength. The ONO layer sequence, moreover, exhibits annealing effects of the thin sites or holes in one of the partial layers, which ultimately leads to a low-defect gate dielectric with high isolation resistance and a relative permittivity that is far above that for silicon dioxide.

It is preferred furthermore that a partial oxide layer of the ONO layer is formed by deposition of a TEOS oxide.

TEOS is an abbreviation for tetraethylorthosilicate. Silicone dioxide forms from this compound at moderate temperatures (up to about 700° C.) by decomposition. During this process, which is also called TEOS pyrolysis, high-value oxide films form, which are characterized, for example, by a high breakdown field strength and a conformal edge coverage.

Another preferred embodiment is characterized by a lithography step in which a mask is created on the dielectric layer and is exposed over a central part of the channel region.

The mask here therefore covers the junction, covered with a dielectric layer, between an active region and the dielectric edge regions. Hence, the central region can be modified without undesirable effects on the covered edge regions.

It is also preferred that the dielectric layer in the exposed regions is removed by an etching step.

In this way, subsequent formation of a dielectric gate layer can occur over the central portion of the channel region in a defined manner, without the properties of the gate layer being influenced by remainders of the previously nonselectively produced dielectric layer.

Another embodiment is characterized in that within the exposed regions a dielectric layer of a second thickness is created, which is smaller than the first thickness.

This layer forms the named gate layer. Because its thickness is smaller than the first thickness, the desired increase in the total thickness of the dielectric layers occurs overall at the junctions and the kink effect is avoided.

It is preferred alternatively that the step for creating a dielectric layer over the channel region has a step of a nonselective creation of a subsequent inner thickness of the dielectric layer.

Within the scope of this embodiment, a lithography step follows first in which a mask is created on the dielectric layer, which is exposed outside a central part of the channel region. In an additional step, the thickness of the dielectric layer in the exposed regions of the mask is increased to the value of the outer thickness.

The mask therefore covers the central part of the channel region, so that edges of the channel region can be modified without undesirable effects on the central part. The otherwise expected reduction in the layer thickness during the transition from active regions to dielectric-filled trench structures is equalized or overcompensated by the increase in the thickness of the dielectric layer in the exposed regions.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows schematically a still incomplete structure of a MOS transistor with a drain region, a source region, a channel region, and a gate electrode and gate layer shown as opened;

FIG. 2 is a section through a MOS transistor with a complete gate electrode and dielectric gate layer, as is derived from the conventional art;

FIG. 3 is a section through a MOS transistor with a complete gate electrode and dielectric gate layer, as is derived as an exemplary embodiment of the invention;

FIG. 4 illustrates characteristics of the MOS transistors of FIGS. 2 and 3;

FIG. 5 illustrates a first alternative of a process sequence for manufacturing a structure according to FIG. 3; and

FIG. 6 is a second alternative of a process sequence for manufacturing a structure according to FIG. 3.

### DETAILED DESCRIPTION

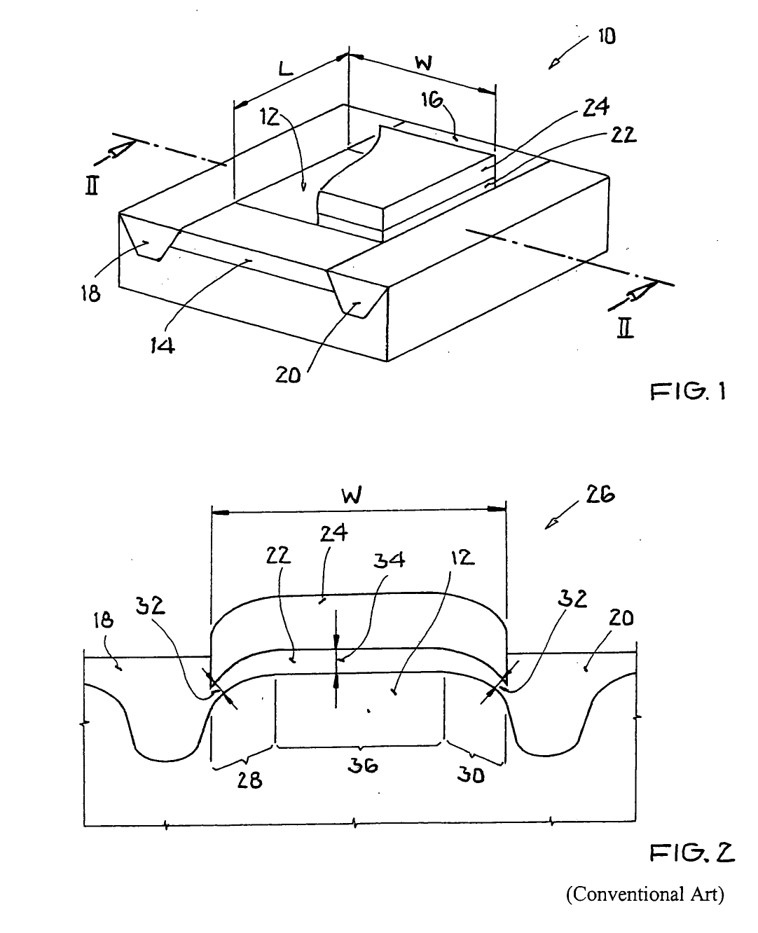

FIG. 1 shows MOS transistor 10 with a channel region 12, which extends between a source region 14 and a drain region 16 with a length L. A width W of channel region 12 is defined by the distance between dielectric-filled trench structures 18 and 20. Source region 14 and drain region 16 are each doped, so that they have a conductivity type opposite to the conductivity type of channel region 12. Channel region 12 is covered by dielectric gate layer 22, on which a highly conductive gate electrode 24 extends.

Dielectric gate layer 22 typically includes an oxide and/or nitride of the semiconductor material of channel region 12. The highly conductive gate electrode 24 can be realized, for example, as a metal layer or as a highly doped polysilicon layer. Both dielectric gate layer 22 and gate electrode 24 are shown only incompletely in FIG. 1, in order to illustrate the layer sequence of channel region 12, dielectric gate layer 22, and gate electrode 24, therefore the MOS diode of MOS transistor 10.

FIG. 2 shows a section through MOS transistor 26 of the conventional art along a line, which runs similar to line 11 in FIG. 1 and cuts channel region 12 along its width W and across its length L. In addition to channel region 12, MOS transistor 26 of FIG. 2 already has all elements 14 to 24 explained in relation to FIG. 1, whereby source region 14 and drain region 16 of FIG. 1 are outside the section line and therefore not shown in FIG. 2. As mentioned previously, variation in the layer thickness of gate layer 22 over the channel width W occurs in prior-art MOS transistors, whose channel width is delimited by STI trenches. In this regard, a first layer thickness 32, which is smaller than a second layer thickness 34 over central part 36 of channel region 12, arises over peripheral parts 28, 30 of channel region 12. It is the relatively small first layer thickness 32 over peripheral parts 28, 30 of channel region 12, which there leads to an earlier inversion, i.e., beginning at a rather low gate potential, in peripheral parts 28, 30 of channel region 12. The associated peripheral leakage currents cause the interfering kink effect.

FIG. 3 shows a section through an improved MOS transistor 38 along a line, which, like line 11 in FIG. 1, cuts channel region 12 along its width W and across its length L. MOS transistor 38 as well has elements 12 to 24 explained in regard to FIG. 1. Nevertheless, the MOS transistor 38 differs from the prior-art MOS transistor 26 of FIG. 2 in first layer thicknesses 32 of gate layer 22 over peripheral parts 28, 30 of channel region 12, which are greater than the second layer thickness 34 of gate layer 22 over central part 36 of channel region 12. A premature start of the inversion in peripheral parts 28 and 30 is avoided thereby, which eliminates the cause of the kink effect.

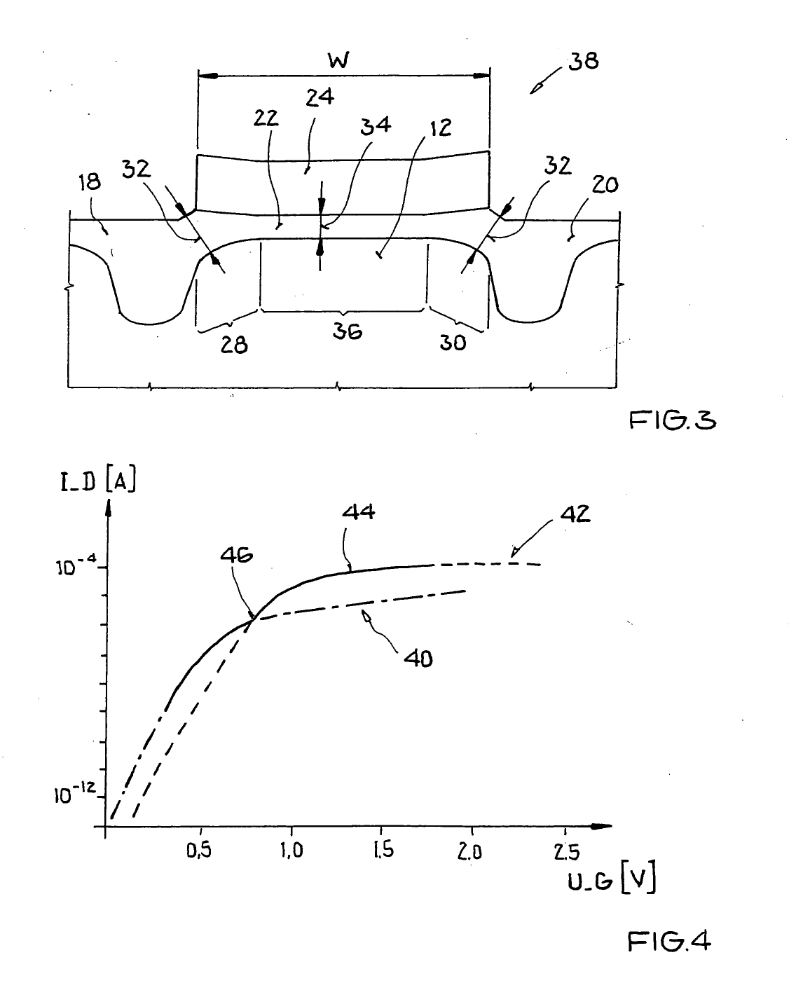

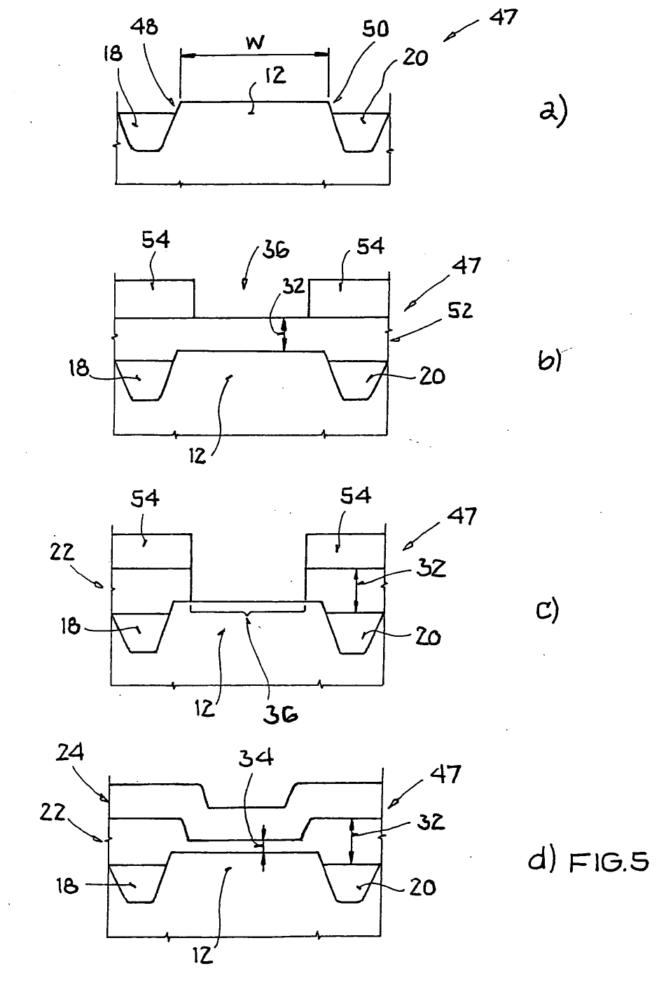

FIG. 4 shows characteristics of the drain current I_D versus the gate voltage U_G. In so doing, the drain current I_D is logarithmically plotted versus U_G, so that an approximately linear pattern occurs in the exponential dependence, predominating in the subthreshold voltage region, of the drain current I_D on the gate voltage U_G. In the case of the dash-dot characteristic 40, the rise in the drain current I_D already begins at lower gate voltages U_G than in the dashed characteristic 42. The dashed characteristic 40 therefore reflects the leakage current behavior of peripheral parts 28, 30 of channel region 12 of prior-art MOS transistor 26 of FIG. 2. The dashed characteristic 42, in contrast, belongs to central part 36 of channel region 12, whose conductivity begins only at higher gate voltages U_G.

At higher gate voltages U_G, the effect of central part 36 of channel region 12 dominates, whereas at low gate voltages U_G, peripheral parts 28, 30 of channel region 12 dominate the behavior of the transistor. Based on the exponential dependence, the non-dominant contributions in the logarithmic plot of FIG. 4 play only a negligible role. For this reason, the total characteristic of a prior-art MOS transistor 26 appears as the solid line 44 in FIG. 4, which has the interfering kink at point 46.

In contrast to prior-art MOS transistor 26 of FIG. 2, peripheral parts 28, 30 in the improved MOS transistor 38 of FIG. 3 do not contribute or contribute only to a negligible extent to the current through channel region 12. In the MOS transistor 38 of FIG. 3, the l_D dependence of the gate voltage U_G is therefore dominated by central part 36 of channel region 12, whose characteristic corresponds to the dashed characteristic 42 of FIG. 4 without the influences of a dash-dot characteristic 40. The dashed characteristic 42 in the case of MOS transistor 38 of FIG. 3 is therefore not corrupted by leakage current effects and therefore has an interfering kink neither at point 46 nor at other characteristic points. In FIG. 4 the characteristic of the improved transistor 38 is obtained qualitatively by the omission of characteristic 40.

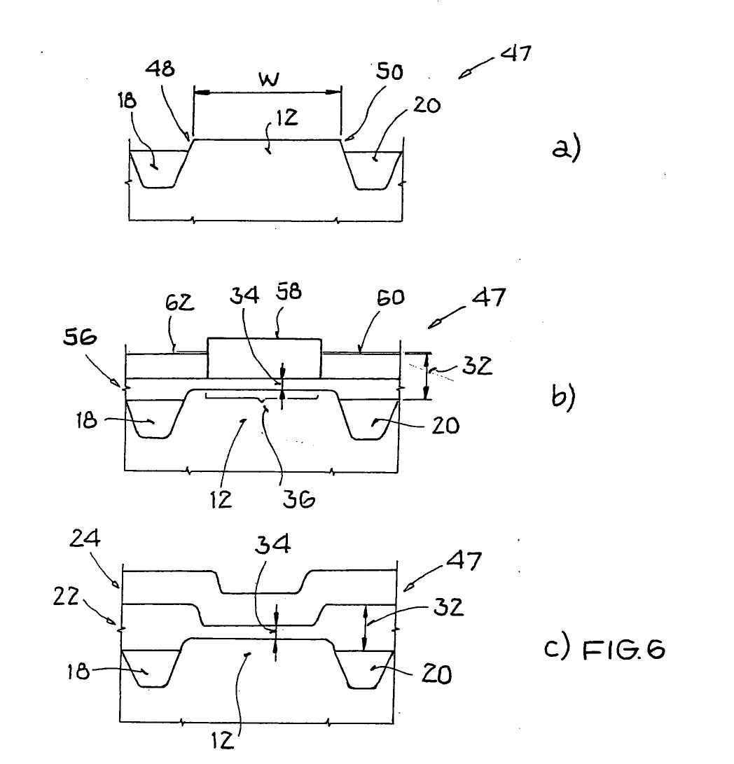

In the following text, alternative embodiments of manufacturing methods for manufacturing MOS transistor structures 38 according to FIG. 3 are explained with reference to FIGS. 5 and 6.

FIG. 5a shows a cross section through semiconductor structure 47 along a subsequent channel width W. The cross section, based on its position, corresponds to the cross sections from FIGS. 2 and 3 along line 11 of FIG. 1. Accordingly, the channel width W is delimited by the dielectric-filled trenches 18, 20 also in the case of FIG. 5. As was already described, increased removal of dielectric material of the fillings of trenches 18 and 20 occurs due to the preceding cleaning steps, so that steps 48, 50 arise in the active semiconductor material of the subsequent channel 12.

FIG. 5b shows the semiconductor structure 47 of FIG. 5a after a step for creating a dielectric layer 52 of a first thickness 32 over channel region 12. As was already mentioned, the dielectric layer 52 can be created as an ONO layer. Alternatively, within the scope of available manufacturing technology, which provides relatively thick dielectric layers, for example, for power transistors, such layer can also be produced. Next, by means of a lithography step, a mask 54 is created on dielectric layer 52 and exposed in a central part 36 of channel region 12. With use of mask 54, in a subsequent etching step, the material of dielectric layer 52 is removed within the openings of the mask 54 down to the surface of active region 12.

As a result, the semiconductor structure 47 shown in FIG. 5c forms. Next, the dielectric layer of a second thickness 34, which is smaller than the first thickness 32, is created over the central part of active range 12. As a result, gate layer 22, which is shown in FIG. 5d and which has an inner, first layer thickness 34, which is smaller than the outer, second layer thickness 32, is formed over central region 36 of channel region 12. FIG. 5d shows the semiconductor structure 47 after the formation of gate layer 22 and the subsequent deposition of a highly conductive gate electrode 24 on the gate layer 22. As is evident, the semiconductor structure 47 of FIG. 5d, in view of the fact that the thickness of gate layer 22 over outer parts of channel region 12 is greater than over its central part, corresponds to the improved MOS transistor 38 of FIG. 3.

Both variants can be used in some cases also together in different components in an integrated circuit. For example, the method can proceed as follows in manufacturing integrated circuits, which have high-voltage DMOS transistors, embedded E²PROM, and low-voltage CMOS components, and in which an ONO layer of the first thickness 32 for the E²PROM cells, a thick gate oxide of comparable thickness for the DMOS components, and a thin gate oxide of the second thickness 34 for the low-voltage CMOS components belong to the process library.

First, the ONO layer is deposited on active regions of some components and patterned. In this context, the patterning occurs so that, as described above, a ONO overlap occurs at the boundaries of the active regions, whereas the other components are completely free of the ONO layer. Thermal oxidation occurs in the next step to manufacture the thick gate oxide, as well as an appropriate patterning. Here as well, an overlap at boundaries of active regions is left in selected components, whereas the thick gate oxide is again removed at other places. Finally, the formation of the thin gate oxide occurs on the central parts of exposed active regions. These possibilities support the simplicity with which a kink or hump can be avoided within the scope of the embodiments presented herein and with an optionally already existing library of process steps.

FIG. 6 shows a alternative manufacturing method, which leads to a comparable result. In this connection, the initial state of the manufacturing method according to FIG. 6, which is shown in FIG. 6a, conforms with the initial state of the method according to FIG. 5, which is shown in FIG. 5a. To avoid repetitions, to understand FIG. 6a, reference is therefore made to the corresponding explanations for FIG. 5a. The semiconductor structure 47 of FIG. 6a is covered with a dielectric layer 56, which over central part 36 of channel region 12 has the second thickness 34 of dielectric gate layer 22 of FIG. 3. Next, mask 58 is created on the part of layer 56 that covers central part 36 of channel region 12. This is followed by an increase in the linear thicknesses of dielectric layer 56 exposed outside mask 58. This is represented in FIG. 6b by dielectric layer sections 60, 62, whose total thickness 32 is greater than the second thickness 34.

This is finally followed by removal of mask 58 and covering of dielectric layers 62, 56, and 60 with a highly conductive gate electrode 24. The result of this step is shown in FIG. 6c, in which the interface between dielectric layers 62 and 56 and 60 and 56 has been left out. The cross section of semiconductor structure 47 of FIG. 6c corresponds to the cross section of semiconductor structure 47 of FIG. 5d, so that the manufacturing methods according to FIGS. 5 and 6 lead to the same result and therefore can be used as an alternative for each other. For the explanation of FIG. 6c, reference is therefore made to the corresponding explanation of FIG. 5d.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A lateral MOS transistor comprising a channel region, which has a channel width delimited by dielectric-filled trenches and which is covered by a gate dielectric, whose layer thickness varies over the channel width, wherein a first layer thickness, which the gate dielectric has over junctions of the channel region to the dielectric-filled trenches, is greater than a second layer thickness, which the dielectric has over a central part of the channel region.

2. A method for manufacturing a lateral MOS transistor with a channel region, which has a channel width delimited by dielectric-filled trenches and in an intermediate step of the method is covered with a gate dielectric, whose layer thickness varies over the channel width, wherein a step of covering the channel region with the gate dielectric comprises the steps of:
creating a dielectric layer over the channel region;
lithographic differentiation of a central part of the channel region from the peripheral parts of the channel region at junctions to the dielectric trenches; and
creating different layer thicknesses of the gate dielectric on the lithographically different parts of the channel region, in which a first layer thickness, arising over the peripheral parts, is greater than a second layer thickness, arising over the central part, of the gate dielectric.

3. The method according to claim 2, wherein the step for creating a dielectric layer over the channel region includes a step of a nonselective creation of a first thickness of the dielectric layer.

4. The method according to claim 3, wherein the step of the nonselective creation of the first thickness has a step of epitaxial growing of an ONO layer.

5. The method according to claim 4, wherein a partial oxide layer of the ONO layer is formed by deposition of a TEOS oxide.

6. The method according to claim 3, wherein, by a lithography step, a mask is created on the dielectric layer and is exposed over the central part of the channel region.

7. The method according to claim 6, wherein the dielectric layer in the exposed regions is removed by an etching step.

8. The method according to claim 7, wherein, within the exposed regions, a dielectric layer of a second thickness is created, which is smaller than the first thickness.

9. The method according to claim 2, wherein the step for creating a dielectric layer over the channel region includes a step of a nonselective creation of a second thickness of the dielectric layer.

10. The method according to claim 9, wherein, by a lithography step, in which a mask is created on the dielectric layer, the mask being exposed outside a central part of the channel region, and wherein, in a further step, the thickness of the dielectric layer in the exposed regions of the mask is increased to the value of the first thickness.
